(19) United States
(12) Patent Application Publication
(10) Pub. No.: US 2024/0038915 A1
(43) Pub. Date: Feb. 1, 2024

(54) METHOD FOR PRODUCING AN ASSEMBLY OF SOLAR CELLS OVERLAPPING VIA AN INTERCONNECTION STRUCTURE

(71) Applicant: COMMISSARIAT A L'ENERGIE ATOMIQUE ET AUX ENERGIES ALTERNATIVES, Paris (FR)

(72) Inventor: Bertrand CHAMBION, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/005,512

(22) PCT Filed: Jul. 26, 2021
(86) PCT No.: PCT/FR2021/051393

§ 371 Date: Jan. 13, 2023

(30) Foreign Application Priority Data
Jul. 29, 2020 (FR) FR2007989

(51) Int. Cl. H01L 31/05

(52) U.S. Cl. CPC H01L 31/0508

(57) ABSTRACT

An assembly of solar cells is provided with a connection structure arranged opposite and between a peripheral zone of a first solar cell and a second peripheral zone of a second solar cell. The connection structure provides increased mechanical flexibility and includes an oblong conductive portion and a set of conductive blocks distributed over the oblong conductive portion, alternately over a first region of the oblong conductive portion and over a second region of the oblong conductive portion opposite the first region.

### TECHNICAL FIELD

The present application relates to the field of photovoltaic (PV) cells, also called solar cells and more particularly that of their assembly and of their interconnection.

It relates to an assembly of solar cells provided with a particular interconnection structure, to the creation of such an assembly as well as to a photovoltaic module including such an assembly.

### PRIOR ART

A conventional technique for interconnection of solar cells is based on the use of an electrically conductive metal band which ensures the electric connection between a cell and the following cell.

Such a type of interconnection is illustrated in FIG. 1A in the particular case of cells 1₁, 1₂, 1₃ with rear-face contact (RCC), the metal band 4 connecting here an electrode 3a disposed at the rear face 2B of a cell 1₁, 1₂ and an electrode 3b disposed at the rear face of another cell 1₂, 1₃.

According to one alternative, illustrated in FIG. 1B, the metal band 4 connects here an electrode 3a disposed at the front face 2A of a cell 1₁ and an electrode 3b disposed at the rear face 2B of another cell 1₂.

In this case, the cells are generally disposed next to each other and this results in a surface 5 which is lost between the cells, which increases the bulk of the assembly and which is consequently called a “dead zone”.

Another assembly technique called “Shingle” allows to limit the bulk and involves superimposing the edges of cells 1₁, 1₂ over a small surface. The interconnection between a conductive zone 7 at the front face 2A of a cell 1₁ and a conductive zone 8 at the rear face 2B of another cell 1₂ is thus carried out via a conductive material 9, of the type braze material added at a zone of overlap between the cells or conductive glue of the ECA (for Electrically Conductive Adhesive) type containing acrylate or epoxy. This interconnection structure has the advantage of not creating a dead zone between cells 1₁, 1₂. However, it results in a rigid mechanical structure that can be fragile when it undergoes significant thermomechanical stresses.

The document “Materials Challenge for shingled cells interconnection” by Beaucarne et al., 6th workshop on metallization and interconnection for crystalline silicon solar cells, 2016, proposes an assembly of the Shingle type by using a glue of the ECA (for Electrically Conductive Adhesive) type with a silicone base (more mechanically flexible than acrylate or epoxy) in order to make the final assembly more flexible. Such a structure allows, however, little deformation in the plane of the cells.

The problem arises of finding a new interconnection technique improved with respect to the disadvantages mentioned above.

### DISCLOSURE OF THE INVENTION

According to the invention, an assembly of solar cells is created comprising:
a first solar cell connected to a second solar cell, the second solar cell being arranged so that a peripheral zone of a rear face of the first cell called “first peripheral zone” overlaps with a peripheral zone of the front face of the second cell called “second peripheral zone”, the assembly further comprising:
   a connection structure arranged facing and between said first peripheral zone and said second peripheral zone,
   said connection structure being formed:
   by at least one oblong conductive portion,
   by a succession of conductive blocks arranged against and in contact with said oblong conductive portion and in a zone of overlap between said first peripheral zone and said peripheral zone, said conductive blocks being alternatingly distributed over a first region (typically a first face) of an oblong conductive portion and over a second region (typically a second face opposite to the first face) of said oblong conductive portion opposite to said first region, one or more first blocks out of said first conductive blocks being in contact with said first peripheral zone, one or more second conductive blocks being in contact with said second peripheral zone.

Such a structure allows to carry out a mechanical decoupling between the cells and to confer onto the assembly an increased flexibility which makes it more resistant to thermomechanical stresses.

Preferably the assembly of said one or more second conductive blocks is offset with respect to the assembly of said one or more first conductive blocks, which allows better deformation in a plane parallel to the cells and contributes to making the assembly more flexible and thus resistant to certain thermomechanical stresses.

Advantageously, one or more or each of said one or more first conductive blocks can be facing an empty space and/or a zone of insulating material disposed between said second region of said oblong conductive portion and said second peripheral zone.

Advantageously, one or more second conductive blocks or each of the second conductive blocks can be arranged facing an empty space and/or a zone of insulating material disposed between said first region of said oblong conductive portion and said first peripheral zone.

According to one possible embodiment this insulating material can be a polymer material. Such a type of material has the advantage of having a low Young's modulus which favours the flexibility of the assembly.

According to a specific embodiment, at least one of said one or more first conductive blocks can be surrounded by a passivation insulating zone arranged between said first region of an oblong conductive portion and said first peripheral zone of the first cell.

According to a specific embodiment, at least one of said one or more second conductive blocks can be surrounded by a passivation insulating zone arranged between said second region of said oblong conductive portion and said first peripheral zone of the first cell.

The oblong conductive portion can be advantageously in the form of at least one conductive wire, or several distinct juxtaposed conductive wires or even a conductive strip, in particular flat.

One specific embodiment provides said conductive blocks in the form of spots of conductive glue, in particular a glue made of polymer material loaded with conductive particles, such as a glue of the ECA type. In this case, the flexibility of the assembly can be favoured.

In this case, a connection structure having a lower electric contact resistance can be obtained.

According to a specific embodiment said conductive blocks have a substantially rectangular or substantially parallelepipedic shape with rounded corners. Such a shape of the conductive blocks can also allow to obtain an increased flexibility of the structure.

The invention relates to a method for creating a solar module provided with an assembly as defined above.

The invention relates more specifically to a method for carrying out an assembly of solar cells, said assembly comprising a first cell connected to a second cell, said second cell being arranged so that a peripheral zone of a rear face of the first cell called “first peripheral zone” overlaps with a peripheral zone of the front face of the second cell called “second peripheral zone”,

the method comprising steps of:
creating a connection structure formed: by at least one oblong conductive portion, and by a succession of conductive blocks said conductive blocks protruding on the oblong portion and being spots of conductive glue said conductive blocks being arranged alternatingly over a first region of an oblong conductive portion and over a second region of said oblong conductive portion opposite to said first region, then,
assembly of the connection structure with the first cell and the second cell, the connection structure being arranged facing and between said first peripheral zone and said second peripheral zone, in a zone of overlap between said first peripheral zone and said peripheral zone, one or more first blocks out of said first conductive blocks being in contact with said first peripheral zone, one or more second conductive blocks being in contact with said second peripheral zone, the assembly of said one or more second conductive blocks being offset with respect to the assembly of said one or more first conductive blocks.

### BRIEF DESCRIPTION OF THE DRAWINGS

The present invention will be better understood upon reading the description of exemplary embodiments given, for purely information and in no way limiting purposes, while referring to the appended drawings in which:

FIGS. 1A, 1B are used to illustrate a conventional technique of assembly and interconnection of solar cells via a conductive band;

FIG. 2 is used to illustrate another technique for assembly and interconnection of solar cells according to the prior art, in which the solar cells overlap and are connected via a braze material or an ECA material;

FIGS. 3, 4, 5 and 6 are used to illustrate a structure for interconnection and assembly of solar cells according to one embodiment, the assembly being carried out without a dead zone and having increased flexibility;

FIG. 7 is used to illustrate the behaviour of the interconnection structure when it undergoes a thermal and/or mechanical stress;

FIG. 8 is used to illustrate differences in performance in terms of average density of accumulated energy in a connection structure with respect to a conventional connection structure;

FIGS. 9A, 9B are used to illustrate various densities of contact conductive blocks in an interconnection structure of a solar cell as implemented according to the invention;

FIG. 10 is used to illustrate differences in electric performance between an interconnection structure and an interconnection structure as implemented according to the present invention;

FIGS. 11, 12, 13 and 14 are used to illustrate an alternative structure for interconnection of solar cells provided with several distinct parallel conductive wires;

FIGS. 15, 16 are used to illustrate another alternative structure for interconnection of solar cells;

FIGS. 17A, 17B, 17C and 17D are used to illustrate steps of an example of a method for assembly and interconnection of solar cells as implemented according to an embodiment of the present invention;

FIGS. 18A, 18B, 18C and 18D are used to illustrate another example of a method for assembly and interconnection of solar cells as implemented according to an embodiment of the present invention.

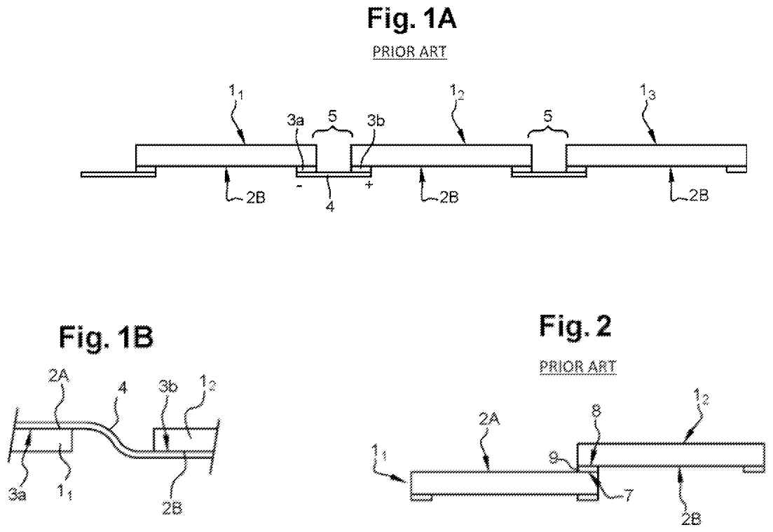

Identical, similar or equivalent parts of the various drawings carry the same numerical references so as to facilitate the passage from one drawing to another.

The various parts shown in the drawings are not necessarily shown on a uniform scale, to make the drawings more readable.

Moreover, in the following description, terms that depend on the orientation of the structure such as “front”, “upper”, “rear”, “lower”, “lateral”, “central”, “peripheral” apply while considering that the structure is oriented in the manner illustrated in the drawings.

### DETAILED DISCLOSURE OF SPECIFIC EMBODIMENTS

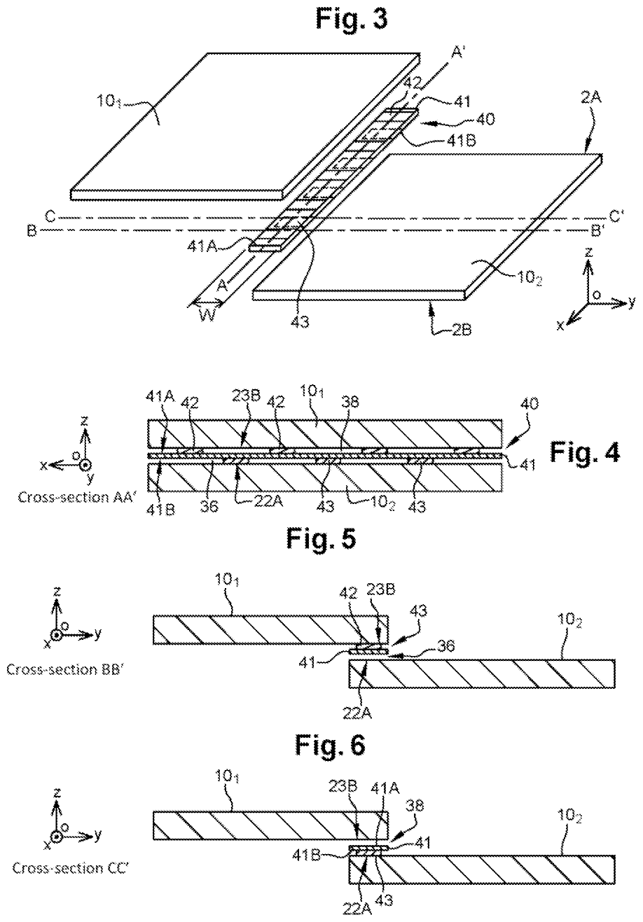

Reference is now made to FIG. 3 giving (via an exploded view) an assembly of solar cells 10₁, 10₂ as implemented according to an embodiment of the present invention.

The solar cells 10₁, 10₂ are formed from a semiconductor substrate, which can be poly or monocrystalline and in particular contain polycrystalline or monocrystalline silicon. Each of the cells 10₁, 10₂ is provided with at least one face 2A called “front face”, receiving light and which is intended to be exposed to solar radiation, and a face 2B called “rear face”, opposite to the front face 2A. The rear face 2B can optionally also be intended to be exposed to solar radiation. In this particular case, the cell is called “bifacial”.

At least one first solar cell 10₁ of this assembly is provided with contacts distributed over the rear face 2B, including one or more contacts (not shown) with respectively one or more zones with n-type doping (in other words having a doping producing an excess of electrons) and one or more contacts (not shown in this drawing) with respectively one or more zones with p-type doping (in other words according to a doping involving producing a deficit of electrons), the n-type zone(s) associated with the p-type zone(s) forming at least one junction.

The assembly is such that a peripheral zone 23B located on the rear face 2B of the first cell 10₁ is disposed facing a peripheral zone 22A of the front face 2A of a second cell 10₂.

The solar cells 10₁, 10₂ are thus assembled here according to an assembly of the type called “shingle”, in other words so as to partly overlap, which allows in particular to create a compact assembly. The overlap can be provided over a distance typically of at least 0.2 mm and which can be between for example 0.5 mm and several millimetres.

Besides the assembly, the connection of the cells 10₁, 10₂ to each other is carried out here using a specific connection structure 40 that is arranged between the cells 10₁, 10₂, and is preferably confined at a region in which they overlap.

This connection structure 40 is formed by an oblong conductive portion 41 which, in the specific exemplary embodiment illustrated in 3, is in the form of a conductive strip. On and in contact with the outer surface of this oblong conductive portion 41, protruding conductive blocks 42, 43 are provided to be respectively placed in contact with the solar cells 10₁, 10₂ and allow to ensure an electric connection from one cell to another.

The conductive blocks 42, 43 are distributed alternatingly over a first region 41A of said conductive portion 41 placed facing the peripheral zone 23B of the first cell 10₁ and over a second region 41B, opposite to the first region, of said conductive portion 41, the second region being disposed facing the peripheral zone 22A of the second cell 10₂. In the case in which the oblong conductive portion 41 is in the form of a conductive strip having a flat shape, the first region 41A and the second region 41B are respectively a first face 41A and a second face 41B opposite to the first face 41A.

The connection structure 40 thus includes one or more first conductive blocks 42 on the first face 41A and one or more second conductive blocks 43 on the face 41B opposite to the first face 41A.

Confining the connection structure 40 and the conductive blocks 42, 43 at the region of overlap of the cells 10₁, 10₂ allows to not obstruct parts, including of the rear face 2B, that it could be desired to expose to solar radiation.

In order to confer flexibility onto the assembly, the blocks 42, 43 are distributed here along an axis AA′, alternatingly on the first face 41A and on the second face 41B, with, preferably, an offset provided from one conductive block 42 to the other 43 along this axis AA′. The assembly of the block(s) 42 formed on the first face 41A is thus offset from the assembly of the block(s) 43 located on the second face 41B.

Thus, in the succession of conductive blocks 42, 43, along the axis AA′ each conductive block 43 is offset from the following block 42.

Thus, as shown by FIGS. 4, 5, 6 (giving cross-sectional views of the assembly respectively according to an axis AA′, an axis BB′, an axis CC′ given in FIG. 3), the conductive blocks 42 and the conductive blocks 43 are misaligned so that a conductive block 42 located on the first face 41A of the conductive strip 41 and in contact with the first cell 10₁ is not disposed facing or entirely facing a second conductive block 43 of the second face 41B but rather at least one space 36 provided between the second face 41B and the second cell 10₂. Likewise, a conductive block 43 located on the second face 41B of the conductive strip 41 and in contact with the second cell 10₂ is not disposed facing or entirely facing a first conductive block 42 located on the first face 41A but at least one space 38 provided between the second face 41B and the first cell 10₁.

This arrangement means that the electric connection between the two cells 10₁ and 10₂ is not established according to a vertical (axis parallel to the vector z of the orthogonal reference frame [O;x;y;z]) conduction path, but according to an S-shaped path. Such an arrangement allows to favour a mechanical decoupling between the cells 10₁, 10₂ and allows a deformation of the cells 10₁, 10₂ after a thermomechanical stress or after a manipulation of the assembly of cells 10₁, 10₂.

The oblong conductive portion 41, when it is in the form of a strip, can be provided with a width W (smaller dimension measured in a plane parallel to the cells and to the plane [O;x;y]) for example between 0.1 and several millimetres, and advantageously between 0.2 mm and 1 mm. Typically, the width W of the strip corresponds to the width of overlap between the cells 10₁, 10₂, for example approximately 1 mm. The strip can also be provided with a thickness e (dimension measured parallel to the axis z) for example between 10 μm and 500 μm, for example approximately 50 μm. The strip can optionally extend over the entire length of a cell.

As for the conductive blocks 42, 43, they can be provided with a thickness for example between 5 μm and 200 μm, for example approximately 50 μm. This thickness is adapted in particular according to the number of blocks, their surface and their rate of distribution on the oblong conductive portion 41.

With regard to the composition of the structure, the oblong conductive portion 41 can be formed by one or more metal material(s) for example such as copper or silver or tinned copper. A specific embodiment provides a conductive portion 41 formed by a core made of conductive material, in particular a metal material such as copper or silver, coated with zone of insulating material forming a discontinuous insulating sheath around the conductive blocks. The insulating material can be a polymer, for example a polyimide such as Kapton™.

The conductive blocks 42, 43 are typically made of a material different than that of the oblong conductive portion 41 and can be in particular added onto this oblong conductive portion 41 typically in the form of spots of conductive glue or zones of braze material.

For example, when the conductive blocks 42, 43 are brazing zones, they can be formed from a metal alloy of the tin-silver-copper type (SnAgCu, also known by the name SAC) which is an alloy without lead. An alloy of the “SAC305” type composed of more than 95% tin, approximately 3.0% silver and approximately 0.5% copper can in particular be used.

When the conductive blocks 42, 43 are spots of conductive glue, an ECA (for Electrically Conductive Adhesive) glue can be used. Such a glue is formed by a polymer matrix, typically of the epoxide, acrylate or silicone type, loaded with conductive particles. For example a silver epoxy glue of the type EPO-TEK® H20E, Loctite® 8282 or Loctite® 8311 can in particular be used.

Thus, with such a connection structure 40, the conductive blocks 42, 43 ensure both the mechanical and electric contact on the cells 10₁, 10₂, while the oblong portion 41 allows to ensure the mechanical decoupling between the cells and the assembly to resist thermal and/or mechanical stresses.

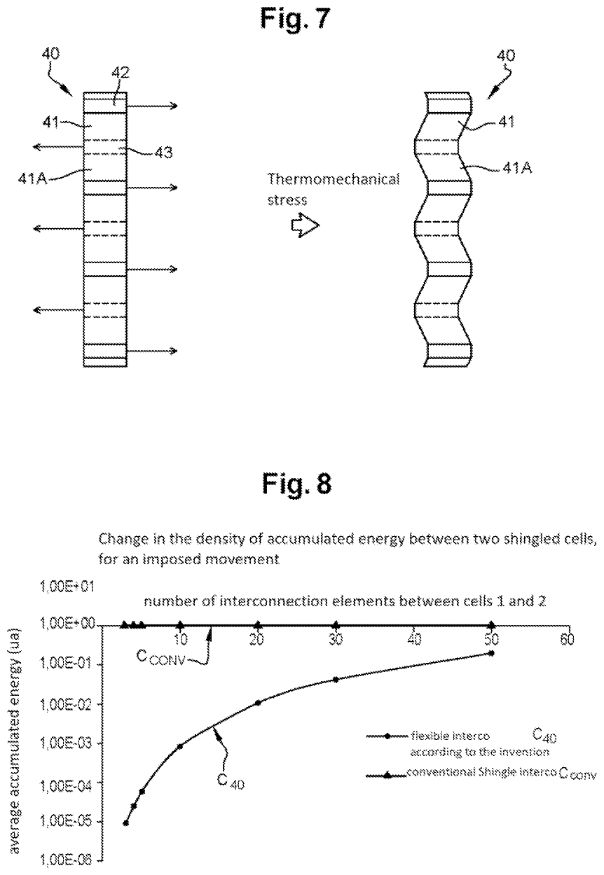

As shown in FIG. 7, such a decoupling can allow the connection structure 40 (shown in a top view) to deform when it undergoes a thermal and/or mechanical stress, without degrading the cells, the latter typically being made of a material having a significant rigidity such as silicon.

In the exemplary embodiment illustrated in FIGS. 3, 4, 5, 6 empty spaces 38, 36 are provided between the connection structure and the cells 10₁, 10₂. Alternatively and as suggested above, these spaces can be at least partly filled by at least one insulating passivation material, for example a material with a low Young's modulus, in particular a polymer such as for example Kapton™.

Digital simulations of stressing via the Ansys® tool were carried out to allow to compare a connection structure as described above with respect to a conventional connection structure implementing a simple conductive band between two overlapping cells. Results of such a simulation are given by the graph of FIG. 8.

For the conventional structure, the interconnection consists of a continuous bead of glue of the ECA type 50 μm thick and 156 mm long, corresponding to an M2 format of solar cells. The material of the glue is considered to have a Young's modulus at 1 GPa.

A connection structure as implemented according to the invention is considered at the same time, with at least three conductive blocks (two on one face, one on another face) on a conductive strip made of copper 156 mm long with a Young's modulus for the copper of 124 GPa.

The number of conductive blocks varies from 3 to 50 to evaluate the change in the deformation capacities of the structure according to the invention.

For each of the established models of simulations, an arbitrary deformation of 1 μm is applied.

Since the geometries and the materials simulated are not identical between the two structures, levels of mechanical stress are not compared. The output piece of data chosen to establish the comparison here is an average density of accumulated elastic energy in the complete interconnection after a deformation of 1 μm. This piece of data can be equated with the inverse of the mechanical flexibility. The results are shown by the curve C₄₀ normalised with respect to the conventional interconnection (C_{conv}).

It is observed on the one hand that the average density of accumulated elastic energy in the connection structure according to the invention always has a value smaller than the reference structure. With regard to the influence of the number of conductive protrusions, even when considering 50 protrusions (which in the present case is equal to an electric connection point every 1.5 mm) the accumulated level of energy is 5 times smaller than that present in the case of a conventional connection structure.

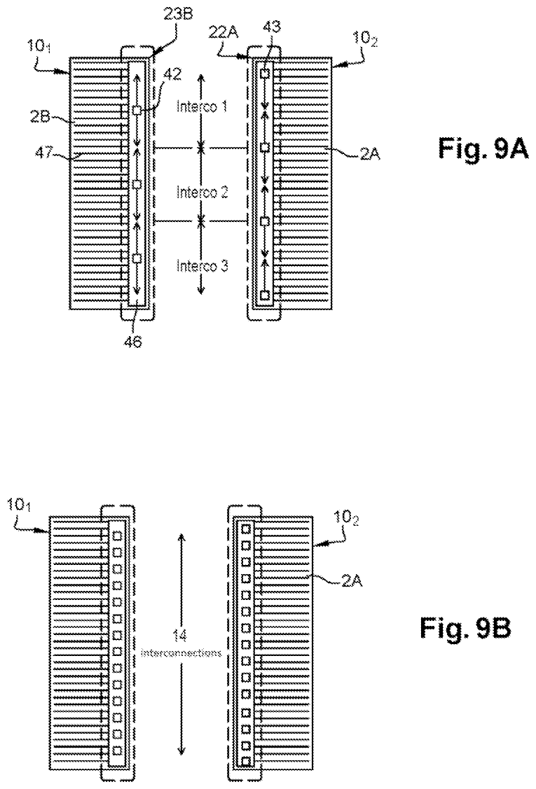

FIGS. 9A and 9B show the cells 10₁, 10₂ before assembly, with various densities of conductive blocks 42, 43 at the zones 23B, 22A.

FIG. 9A allows to illustrate a first case of a low number n of conductive blocks, for example equal to 3, along each cell. In this case, in order to distribute the current in all the conductive pins 47 on the cell surface, a greater thickness of the conductive zones 46 on which they are in contact and that are made for example by screen printing with silver paste can be provided.

In a second case (FIG. 9B) of a significant number of conductive blocks along the cells to be connected (n=50), the conductive zone 46 can be provided with a thickness of a conventional Shingle assembly.

The geometric optimum of the connection structure and in particular the number, the size and the density of the conductive blocks 42, 43 depends on a compromise between a necessary mechanical flexibility while guaranteeing sufficient electric performance of the interconnection.

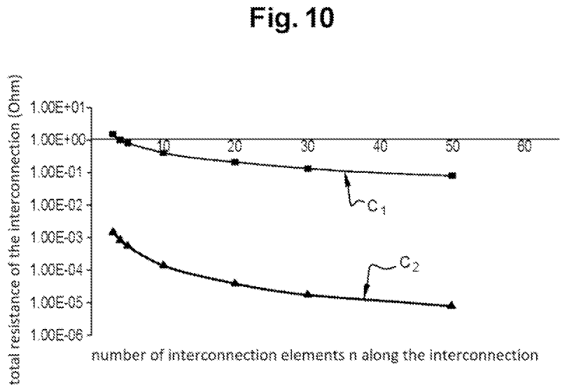

FIG. 10 illustrates the result of a comparison between the series resistance of a first connection structure according to the invention (curve C₁) and that of a second connection structure according to the invention (curve C₂).

The first connection structure according to the invention (curve C₁) is formed here by a band of copper having thickness*length*width dimensions of 0.05*156*1 mm and conductive blocks protruding on the band and formed by a braze material of the SAC305 type. The brazing zones have dimensions of 0.05*1*1 mm (thickness*length*width).

The series resistance of a second interconnection as implemented according to the invention with spots of glue of the ECA type is also illustrated (curve C₂).

The comparison is carried out using an analytical calculation (R=(Rho*L)/S), with R the electric resistance of the material, Rho the resistivity of the material, L the length and S its cross-section, while considering resistivities for the copper of 17e-9 ohm·m, for the SAC305 braze: 1.3e-6 ohm·m, for the ECA glue 4^{e}-2 ohm·m.

The results are presented in the form of curves C₁, C₂ according to the number n of spots of glue or of brazing zones along the zone of overlap between cells.

The structure according to the invention allows to use a material of the braze type for the connections on the cells. Indeed, it is observed that the interconnection proposed in this invention always has a theoretical electric resistance lower than that of a conventional structure.

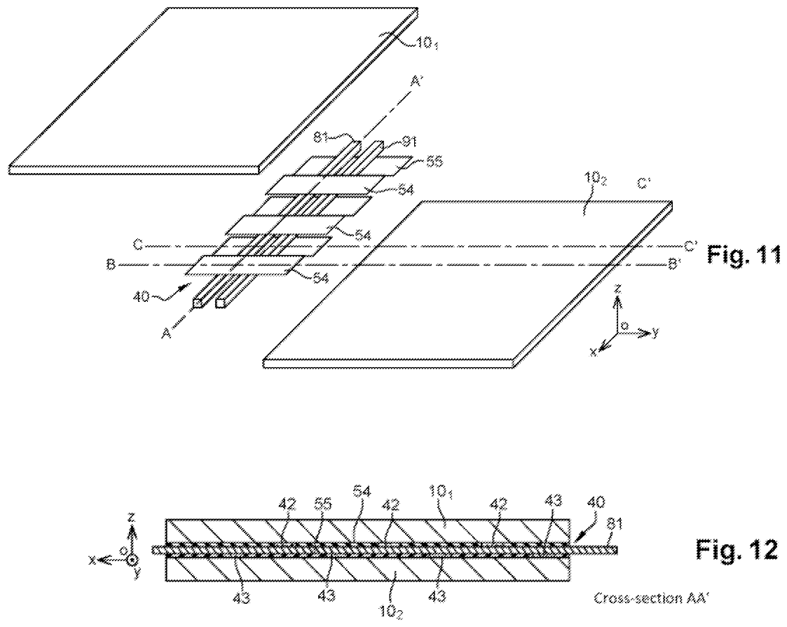

Another example of a structure for interconnection between cells 10₁, 10₂ is given in FIGS. 11 to 14 respectively giving an exploded view, a view of a cross-section AA, a view of a transverse cross-section BB′, and another view of a cross-section CC′ according to another transverse cutting plane. The oblong portion of the connection structure this time takes the form of conductive wires 81, 91 juxtaposed and preferably disposed parallel to one another.

The conductive blocks 42, 43 (not shown in FIG. 11 for simplification purposes) respectively distributed on the conductive wires 81, 91 and under the conductive wires 81, 91 can have an arrangement similar to that described above. The structure includes here passivation zones 54, 55 respectively distributed on the conductive wires 81, 91, and under the conductive wires 81, 91. Thus, one or more passivation zones 54 are arranged between the first cell 10₁ and an upper face of the conductive wires 81, 91, while one or more other passivation zones 55 are arranged between the second cell 10₂ and a lower face of the conductive wires 81, 91 opposite to the upper face. Each passivation zone 54 (respectively 55) can be provided between two conductive blocks 42 (respectively 43).

The passivation zones 54, 55 can be in the form of a film or of a layer of insulating material for example a polymer material such as Kapton™, and transparent in the case in which the film is wider than the zone of overlap of the cells, and added onto the conductive wires 81, 91.

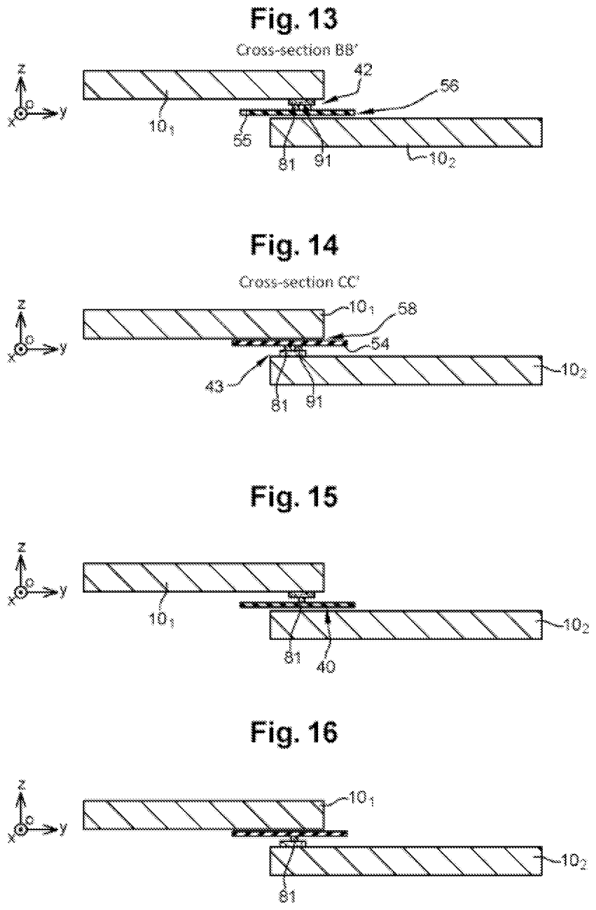

As visible in FIGS. 13 and 14, the thickness of the passivation zones can be less than that of the conductive blocks 42, 43. An empty space 56 (respectively 58) can thus be made between a passivation zone 55 (respectively 54) and the cell 10₂ (respectively 10₂) facing which this passivation zone is located.

An alternative embodiment with this time a single conductive wire 81 to carry out the connection between conductive blocks 42 connected to the cell 10₁ and conductive blocks 42 connected to the cell 10₁ is given in the transverse cross-sectional views of FIGS. 15 and 16.

The conductive wire 81 has in the example illustrated a parallelepipedic shape. A wire having a cylindrical shape can also be used.

With regard to its manufacturing, a connection structure 40 as described above can be made in several ways.

A first possibility involves functionalising the oblong portion 41 then carrying out the assembly with the cells. Thus, the conductive blocks 42, 43 are formed on the oblong portion 41, for example on an upper face and on a lower face of a conductive strip, then the interconnection structure is disposed in such a way that it is interposed in the zone of overlap between the cells 10₁, 10₂. Then the assembly is carried out.

One can start for example from a conductive strip on which one or more conductive blocks are made, for example in the form of spots of conductive glue on a first face. The conductive blocks can be made for example by screen printing by using a mask, optionally temporary, arranged on the front face and including one or more openings exposing the first face of the conductive strip.

Then, one or more conductive blocks are formed on a second face for example spots of conductive glue on a second face opposite to the first face. Likewise, conductive blocks can be made on the second face, for example by screen printing, by using for example the same mask or another mask, optionally temporary, arranged on the second face and including one or more openings exposing the second face of the conductive strip.

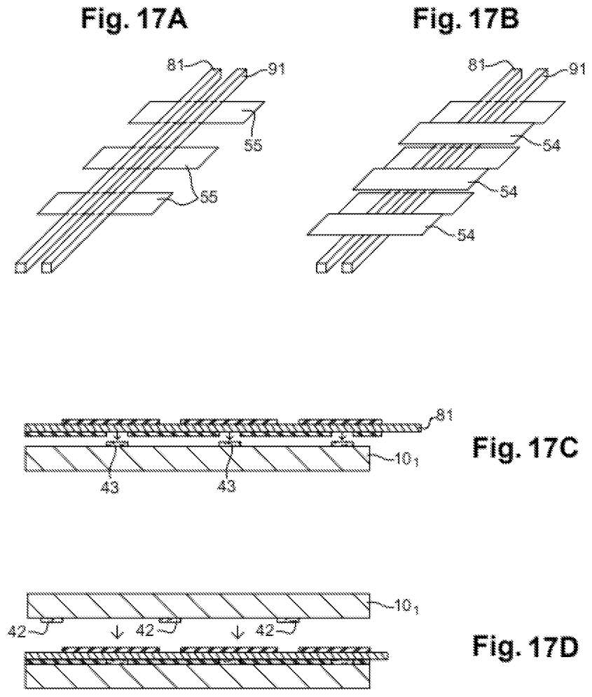

According to an alternative illustrated in FIGS. 17A-17D, passivation zones 55, for example made of polymer on a face or on a side of the oblong portion (FIG. 17A), here formed by juxtaposed conductive wires 81, 91, and other passivation zones 54 on the opposite face or on the opposite side are created. Then, the structure thus obtained is assembled with a cell 10₂ on which conductive blocks 43 in the form of spots of glue or brazing zones are disposed (FIG. 17C). Then, other conductive blocks 42 in the form of spots of glue or brazing zones can be added onto the other cell 10₁ that is then assembled with the structure previously obtained (FIG. 17D).

Alternatively to this step, other conductive blocks can be added in the form of spots of glue or brazing zones onto the conductive wires 81, 91 and then the assembly with the other cell is carried out.

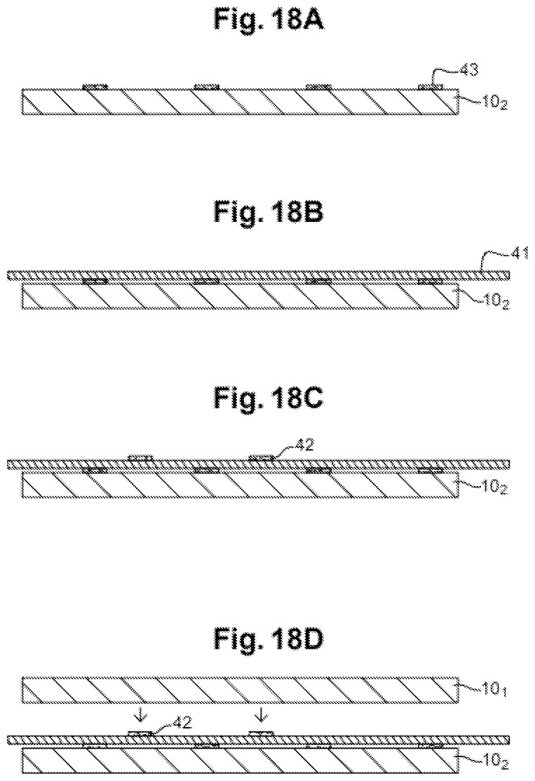

According to another alternative illustrated in FIGS. 18A-18D, it is possible first of all to create one or more conductive blocks 43, for example spots of glue or of braze on a peripheral zone of a solar cell 10₂ (FIG. 18A). Then, the oblong conductive portion 41 is disposed on these conductive blocks 43 (FIG. 18B).

Then (FIG. 18C), in another assembly of conductive blocks 42 on the oblong conductive portion for example spots of glue or of braze are formed. Then (FIG. 18D) the other cell 10₁ is disposed on this other assembly of blocks 42.

Such an alternative is adapted in particular when the blocks are in the form of drops of braze (brazing paste).

According to another alternative, it is also possible to create one or more conductive blocks on each cell then add each cell provided with the conductive blocks onto one of the faces of the conductive strip.

According to a specific embodiment, a distribution of the material of the conductive blocks is carried out simultaneously in several points of the conductive strip, for example via a plurality of distribution needles delivering drops of glue, in particular an ECA glue.

1. A method for producing an assembly of solar cells, said assembly comprising a first cell connected to a second cell, said second cell being arranged so that a first peripheral zone of a rear face of the first cell overlaps with a second peripheral zone of a front face of the second cell,
the method comprising:
creating a connection structure formed by at least one oblong conductive portion and by a succession of conductive blocks, said conductive blocks protruding on the oblong portion and being comprised of conductive glue, and said conductive blocks being arranged alternatingly on a first region of the at least one oblong conductive portion and on a second region of said at least one oblong conductive portion opposite to said first region, then
assembling the connection structure with the first cell and the second cell, the connection structure being arranged facing and between said first peripheral zone and said second peripheral zone, in a zone of overlap between said first peripheral zone and said peripheral zone, one or more first conductive blocks out of said conductive blocks being in contact with said first peripheral zone, one or more second conductive blocks of said conductive blocks being in contact with said second peripheral zone, the assembly of said one or more second conductive blocks being offset with respect to the assembly of said one or more first conductive blocks.

2. The method according to claim 1, wherein at least one of:
each of said one or more first conductive blocks is arranged facing an empty space and/or a zone of insulating material disposed between said second region of said at least one oblong conductive portion and said second peripheral zone, and
each of said one or more second conductive blocks is arranged facing an empty space and/or a zone of insulating material disposed between said first region of said oblong conductive portion and said first peripheral zone of the first cell.

3. The method according to claim 2, wherein said insulating material is a polymer material.

4. The method according to claim 1, comprising at least one of said one or more first conductive blocks being surrounded by a passivation insulating zone arranged between said first region of the at least one oblong conductive portion and said first peripheral zone.

5. The method according to claim 1, comprising at least one of said one or more second conductive blocks being surrounded by a passivation insulating zone arranged between said second region of said at least one oblong conductive portion and said second peripheral zone.

6. The method according to claim 1, wherein said at least one oblong conductive portion is formed by at least one conductive wire.

7. The method according to claim 1, wherein said conductive blocks are provided with rounded corners.

8. The method according to claim 1, wherein said at least one oblong conductive portion is formed by several distinct juxtaposed conductive wires.

9. The method according to claim 1, wherein said at least one oblong conductive portion is formed by a conductive strip.
